(19) United States
(12) Patent Application Publication
(10) Pub. No.: US 2011/0177640 A1
(43) Pub. Date: Jul. 21, 2011

(54) Method for manufacturing an organic light emitting diode display

(76) Inventors: Ji-Hwan Han, Yongin-City (KR); Chang-Soo Kim, Yongin-city (KR); Yun-Sik Ham, Yongin-city (KR); Young-Ro Jung, Yongin-city (KR); Beung-Hwa Jeong, Yongin-city (KR)

(21) Appl. No.: 12/926,762

(22) Filed: Dec. 8, 2010

(30) Foreign Application Priority Data
Jan. 19, 2010 (KR) 10-2010-0004931

(51) Int. Cl. H01L 51/56

(52) U.S. Cl. 438/35; 438/34; 257/E51.022; 257/E51.018

(57) ABSTRACT

A method for manufacturing an organic light emitting diode (OLED) display includes forming a first electrode having different thicknesses corresponding to a first pixel, a second pixel, and a third pixel, forming a first emission layer, a second emission layer, and a third emission layer respectively corresponding to the first pixel, the second pixel, and the third pixel, and forming a second electrode on the first emission layer, the second emission layer, and the third emission layer, wherein forming the first electrodes includes forming a first electrode material layer on the substrate, forming a photoresist pattern having different thicknesses corresponding to the first pixel, the second pixel, and the third pixel, respectively, and etching the first electrode material layer along with the photoresist pattern.

### BACKGROUND

1. Field

Embodiments relate to a method for manufacturing an organic light emitting diode (OLED) display.

2. Description of the Related Art

An organic light emitting diode (OLED) display has a self-light emitting characteristic such that it is advantageous for down-sizing and weight reduction, since a separate light source is not required. Also, the organic light emitting diode (OLED) display has high quality characteristics such as low power consumption, high luminance, and high reaction speed, and has been spotlighted as a next-generation display device for, e.g., portable electronic devices.

The organic light emitting diode (OLED) display may include an organic light emitting element (organic light emitting diode) having an anode, an organic emission layer, and a cathode, and a thin film transistor driving the organic light emitting element. Electrons and holes are injected into the organic emission layer from the anode and the cathode, respectively, and when excitons (formed by coupling of the holes and electrons that are injected into the organic emission layer) drop from an exited state to a ground state, light is emitted by the released energy. The display of the light emitting diode (OLED) display is realized through the light emitted thereby.

The organic emission layer may be formed by a deposition process using a fine metal mask (FMM). To improve the resolution of the display device, a method executing a plurality of deposition processes of red, green, and blue organic emission layers may be used. In this case, defects such as a black point and a spot may be increased by the plurality of deposition processes, and as a result the yield of the organic light emitting diode (OLED) display may be deteriorated. Also, the same organic emission layers are formed through the plurality of deposition processes such that the cost of the light emitting material consisting of the organic emission layer is also increased.

The above information disclosed in this Background section is only for enhancement of understanding of the background of the described technology and therefore it may contain information that does not form the prior art that is already known in this country to a person of ordinary skill in the art.

### SUMMARY

It is a feature of an embodiment to provide a method for manufacturing an organic light emitting diode display that reduces a number of deposition processes of red, green, and blue organic emission layers and maintains uniform luminous efficiency.

At least one of the above and other features and advantages may be realized by providing a method for manufacturing an organic light emitting diode (OLED) display, the method including forming a first electrode having different thicknesses corresponding to a first pixel, a second pixel, and a third pixel, forming a first emission layer, a second emission layer, and a third emission layer respectively corresponding to the first pixel, the second pixel, and the third pixel, and forming a second electrode on the first emission layer, the second emission layer, and the third emission layer. Forming the first electrodes may include forming a first electrode material layer on the substrate, forming a photoresist pattern having different thicknesses corresponding to the first pixel, the second pixel, and the third pixel, respectively, and etching the first electrode material layer along with the photoresist pattern.

The first electrode corresponding to the first pixel may be thicker than the first electrode corresponding to the second pixel, and the first electrode corresponding to the second pixel may be thicker than the first electrode corresponding to the third pixel.

The photoresist pattern corresponding to the first pixel may have a first thickness, the photoresist pattern corresponding to the second pixel may have a second thickness that is less than the first thickness, and the photoresist pattern corresponding to the third pixel may have a third thickness that is less than the second thickness.

The photoresist pattern may be formed using a mask that provides respectively different amounts of exposure to each of the first pixel, the second pixel, and the third pixel.

In the mask, the exposure amount of the photoresist pattern corresponding to the first pixel may be less than the exposure amount of the photoresist pattern corresponding to the second pixel, and the exposure amount of the photoresist pattern corresponding to the second pixel may be less than the exposure amount of the photoresist pattern corresponding to the third pixel.

The mask may include light blocking patterns corresponding to the first pixel, the second pixel, and the third pixel, respectively, and the light blocking pattern corresponding to the first pixel may be thicker than the light blocking pattern corresponding to the second pixel, and the light blocking pattern corresponding to the second pixel may be thicker than the light blocking pattern corresponding to the third pixel.

The light blocking pattern may include chromium.

The first electrode material layer may be dry-etched through the photoresist pattern.

The first pixel may be a red pixel, the second pixel may be a green pixel, and the third pixel may be a blue pixel.

At least one of the above and other features and advantages may be realized by providing a method for manufacturing an organic light emitting diode (OLED) display, the method including forming a pixel electrode corresponding to a first pixel and a pixel electrode corresponding to a second pixel, where the first pixel includes an emission material having a first luminous efficiency and the second pixel has a second luminous efficiency that is greater than the first luminous efficiency, and forming a second electrode on the first emission layer and the second emission layer. Forming the pixel electrodes may include forming an electrode material layer on the substrate, and simultaneously forming the pixel electrode corresponding to the first pixel and the pixel electrode corresponding to the second pixel by etching the electrode material layer using a photoresist pattern to control an amount of the electrode material layer that is removed by the etching, the photoresist pattern having a first thickness in a region corresponding to the first pixel and a second thickness in a region corresponding to the second pixel, the first thickness being greater than the second thickness.

### BRIEF DESCRIPTION OF THE DRAWINGS

The above and other features and advantages will become more apparent to those of skill in the art by describing in detail example embodiments with reference to the attached drawings, in which:

FIG. 1 illustrates a layout view of an organic light emitting diode (OLED) display according to a first example embodiment.

FIG. 2 illustrates a cross-sectional view taken along the line II-II of FIG. 1.

FIG. 3 illustrates a cross-sectional view taken along the line of FIG. 1.

FIG. 4 illustrates a flowchart of a method for manufacturing an organic light emitting diode (OLED) display according to a second example embodiment.

FIG. 5A to FIG. 5D illustrate cross-sectional views of stages in a process of forming red, green, and blue pixel electrodes in an organic light emitting diode (OLED) display according to a third example embodiment.

### DETAILED DESCRIPTION

Korean Patent Application No. 10-2010-0004931, filed on Jan. 19, 2010, in the Korean Intellectual Property Office, and entitled: “Method for Manufacturing an Organic Light Emitting Diode Display,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. In order to describe the exemplary embodiments more clearly, parts that are not related to the description may be omitted from the drawings.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As described herein, a manufacturing method for an organic light emitting diode (OLED) display according to embodiments may simplify the process of forming pixel electrodes having the different thicknesses.

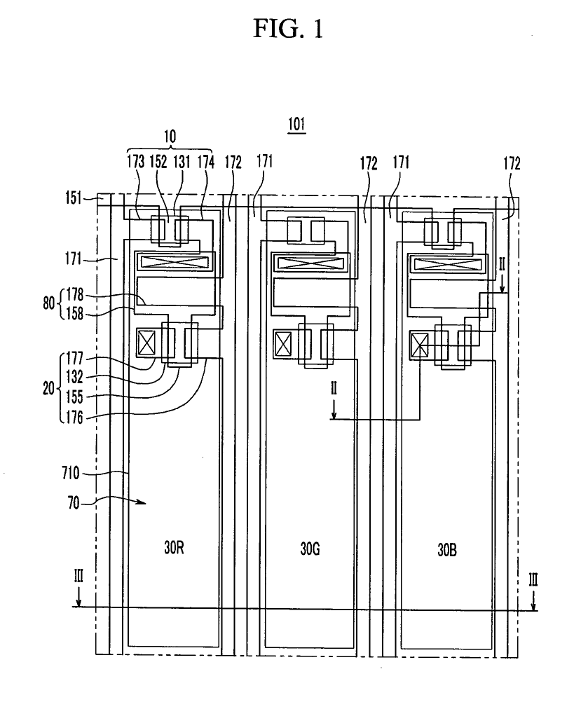

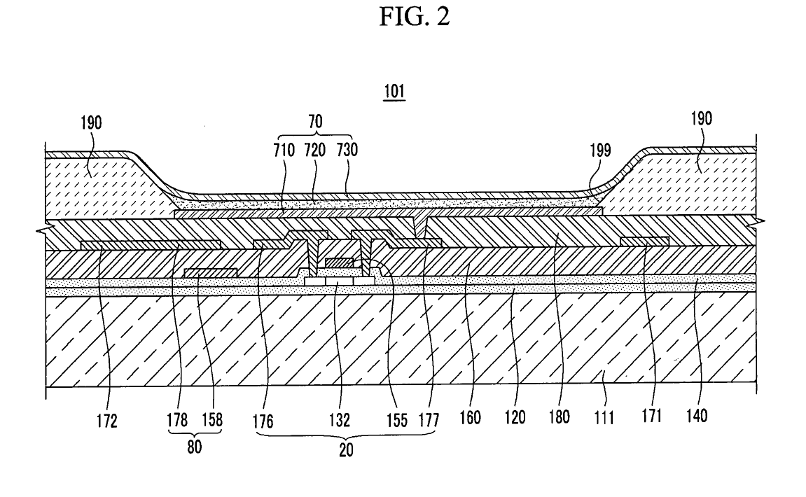

FIG. 1 illustrates a layout view of an organic light emitting diode (OLED) display according to a first example embodiment, and FIG. 2 illustrates a cross-sectional view taken along the line II-II of FIG. 1.

In FIG. 1 and FIG. 2, an organic light emitting diode (OLED) display is illustrated as an active matrix (AM)-type OLED display 101 in a 2Tr-1Cap (two transistor, one capacitor) structure in which two thin film transistors (TFTs) 10 and 20 and one capacitor 80 are formed in one pixel, but the OLED display can have various other structures. For example, three or more TFTs and two or more capacitors may be provided in one pixel of the OLED display, and separate wires may be further provided. The pixel may be a minimum unit for displaying an image, and the OLED display may display an image by using a plurality of pixels.

Referring to FIG. 1 and FIG. 2, an organic light emitting diode (OLED) display 101 may include a switching thin film transistor 10, a driving thin film transistor 20, the capacitor 80, and an organic light emitting element (organic light emitting diode, OLED) 70 that are respectively formed in a plurality of pixels defined on a substrate 111. The OLED display 101 may further include gate lines 151 disposed along one direction, and data lines 171 and common power lines 172 that respectively cross the gate lines 151 while insulated therefrom.

One pixel may be defined by a boundary of a gate line 151, a data line 171, and a common power line 172.

A buffer layer 120 may be disposed between the substrate main body 111, and the switching thin film transistor 10 and the organic light emitting element 70. The buffer layer 120 may help flatten the surface while preventing the intrusion of undesired components like impurities or moisture. The buffer layer 120 may be omitted depending upon the kind and processing conditions of the substrate main body 111.

The organic light emitting element 70 may include the first electrode (hereinafter, “pixel electrode”) 710, an organic emission layer 720 formed on the pixel electrode 710, and a second electrode (hereinafter, “common electrode”) 730 formed on the organic emission layer 720. A pixel electrode 710 is formed for each pixel, respectively. Thus, the organic light emitting diode display 101 may have a plurality of pixel electrodes 710 spaced apart from each other.

The pixel electrode 710 may be an anode serving as a hole injection electrode, and the common electrode 730 may be a cathode serving as an electron injection electrode. In another implementation, the pixel electrode 710 may be the cathode and the common electrode 730 may be the anode according to the driving method of the organic light emitting diode (OLED) display 101.

Light may be emitted when excitons, created by combination of holes and electrons injected to the organic emission layer 720, drop from an exited state to a ground state.

The capacitor 80 may include a pair of capacitor plates 158 and 178 disposed with an interlayer insulating layer 160 interposed therebetween. The interlayer insulating layer 160 may be a dielectric material. The charges charged to the capacitor 80 and the voltage between the first and the second capacitor electrode plates 158 and 178 determines the capacitance.

The switching thin film transistor 10 may include a switching semiconductor layer 131, a switching gate electrode 152, a switching source electrode 173, and a switching drain electrode 174. The driving thin film transistor 20 may include a driving semiconductor layer 132, a driving gate electrode 155, a driving source electrode 176, and a driving drain electrode 177. The switching and driving semiconductor layers 131 and 132, and the switching and driving gate electrodes 152 and 155, may be disposed with the gate insulating layer 140 interposed therebetween. The switching and driving semiconductor layers 131 and 132, the switching and driving source electrodes 173 and 176, and the switching and driving drain electrodes 174 and 177 may be connected to each other through contact holes formed in the gate insulating layer 140 and the interlayer insulating layer.

The switching thin film transistor 10 may be used as a switch for selecting pixels to emit light. The switching gate electrode 152 may be connected to the gate line 151, and the switching source electrode 173 may be connected to the data line 171. The switching drain electrode 174 may be separated from the switching source electrode 173 and may be connected to one capacitor plate, e.g., capacitor plate 158.

The driving thin film transistor 20 may apply a driving voltage to the pixel electrode 710 to excite the organic emissive layer 720 of the organic light emitting diode 70 in the selected pixel. The driving gate electrode 155 may be connected to the capacitor plate 158 connected to the switching drain electrode 174. The driving source electrode 176 and the other capacitor plate 178 may be respectively connected to the common power line 172. The driving drain electrode 177 may be connected to the pixel electrode 710 of the organic light emitting element 70 through a contact hole of a planarization layer 180. In another implementation, the planarization layer 180 may be omitted, and the driving drain electrode 177 and the pixel electrode 710 may be at the same layer. The pixel electrodes 710 may be insulated from each other by a pixel definition layer 190 formed on the planarization layer 180.

The switching thin film transistor 10 may be operated by the gate voltage applied to the gate line 151, and may transmit the data voltage applied to the data line 171 to the driving thin film transistor 20

A voltage with a value corresponding to a difference between the common voltage applied to the driving thin film transistor 20 from the common power line 172 and the data voltage transmitted from the switching thin film transistor 10 may be stored at the capacitor 80. A current corresponding to the voltage stored at the capacitor 80 may flow to the organic light emitting diode 70 through the driving thin film transistor 20 to thereby excite the organic light emitting diode 70.

In the organic light emitting element 70, the pixel definition layer 190 covering the pixel electrode 710 may have an opening 199 exposing the pixel electrode 710, thereby covering the region except for the opening 199. The organic emission layer 720 may be formed on the pixel electrode 710 in the opening 199 of the pixel definition layer 190, and the common electrode 730 may be formed on the pixel definition layer 190 and the organic emission layer 720.

The organic emission layer 720 may be made of, or may include, a low molecular weight organic material or a high molecular weight organic material. The organic emission layer 720 may be formed in a multi-layer structure. The multi-layer structure may include one or more of a hole injection layer (HIL), a hole transport layer (HTL), an emission layer, an electron transport layer (ETL), and an electron injection layer (EIL). In an example implementation of the organic emission layer 720, the hole injection layer (HIL) is disposed on the pixel electrode 710 (the anode), and is sequentially overlaid with the hole transport layer (HTL), the emission layer, the electron transport layer (ETL), and the electron injection layer (EIL).

Examples of the low molecular weight material may include an aluminum quinolinate complex such as Alq₃, anthracene, cyclopentadiene, BeBq2, Almq, ZnPBO, Balq, DPVBi, BSA-2, and 2PSP. Examples of the high molecular weight material may include polyphenylene (PPP) and derivatives thereof, poly(p-phenylenevinylene) (PPV) and derivatives thereof, and polythiophene (PT) and derivatives thereof.

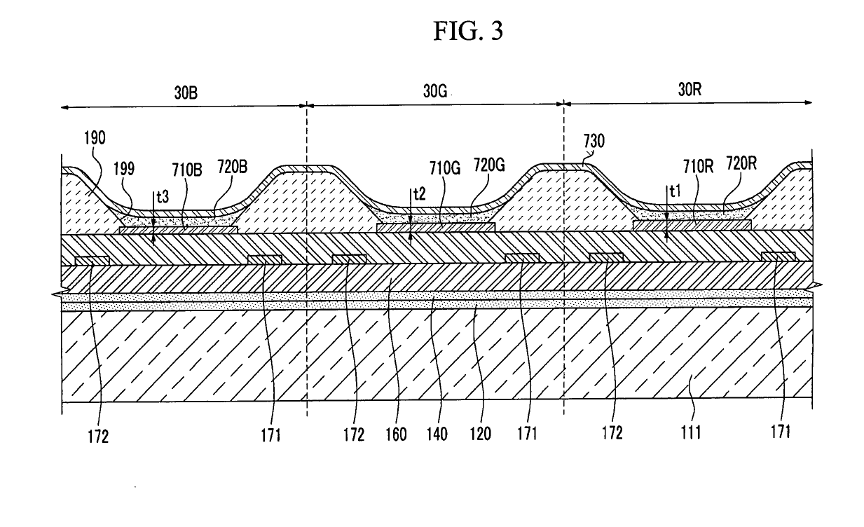

FIG. 3 illustrates a cross-sectional view taken along the line of FIG. 1. Referring to FIG. 3, a red pixel 30R, a green pixel 30G, and a blue pixel 30B may form one pixel. Red, green, and blue organic emission layers may be formed in the red, green, and blue pixels 30R, 30G, and 30B, respectively. The red, green, and blue organic emission layers may each have different luminous efficiencies. For example, the red emission layer may have a luminous efficiency that is less than that of the green emission layer, and the green emission layer may have a luminous efficiency that is less than that of the blue emission layer.

The thicknesses of the respective pixel electrodes 710 may be controlled to compensate for the different luminous efficiencies. For example, the red, green, and blue pixel electrodes 710R, 710G, and 710B (which are respectively formed in the red, green, and blue pixels 30R, 30G, and 3013) may have different thicknesses corresponding to the differences of the luminous efficiencies of the red, green, and blue organic emission layers 720R, 720G, and 720B.

In an embodiment, the electrode thicknesses decrease in the sequence of the red pixel electrode 710R (thickest), the green pixel electrode 710G, and the blue pixel electrode 710B (thinnest) in correspondence with the increasing luminous efficiencies in the sequence of the red organic emission layer 720G (lower than that of the green organic emission layer 720G and lower than that of the blue organic emission layer 720B), the green organic emission layer 720G (higher than that of the red organic emission layer 720G and lower than that of the blue organic emission layer 720B), and the blue organic emission layer 720B (higher than that of the red organic emission layer 720G and higher than that of the green organic emission layer 720G). Thus, in an implementation a thickness t1 of the red pixel electrode 710R may be greater than a thickness t2 of the green pixel electrode 710G, and the thickness t2 of the green pixel electrode 710G may be greater than a thickness t3 of the blue pixel electrode 710B.

As described above, when the pixel electrode corresponding to the organic emission layer made of the material having low luminous efficiency is thickly formed, the low luminous efficiency of the corresponding organic emission layer may be compensated.

In the example illustrated in FIG. 3, the luminous efficiency increases in the sequence of the red organic emission layer 720R, the green organic emission layer 720G, and the blue organic emission layer 720B. However, it will be understood that the sequence of the luminous efficiency of the red, green, and blue organic emission layer 720R, 720G, and 720B may vary depending on the emissive materials used, and the thickness of the pixel electrode 710 in the pixel having the lowest luminous efficiency among the red, green, and blue pixels 30R, 30G, and 30B may be the largest, as in the above-described embodiment.

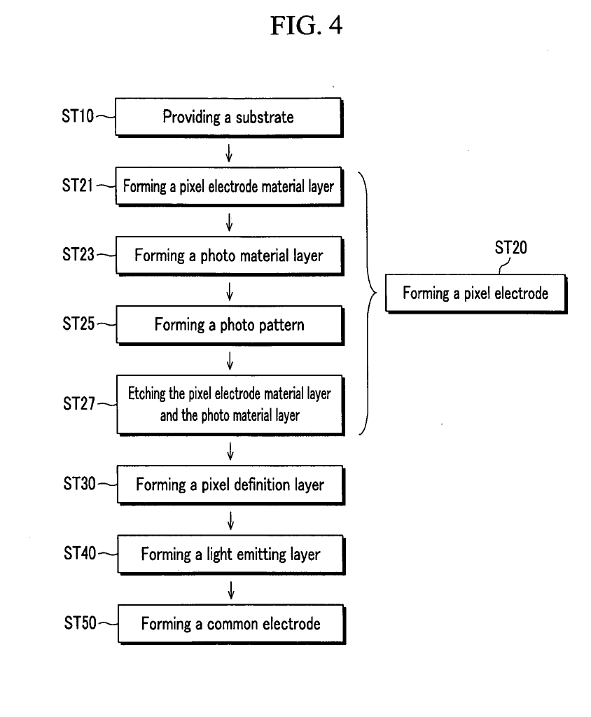

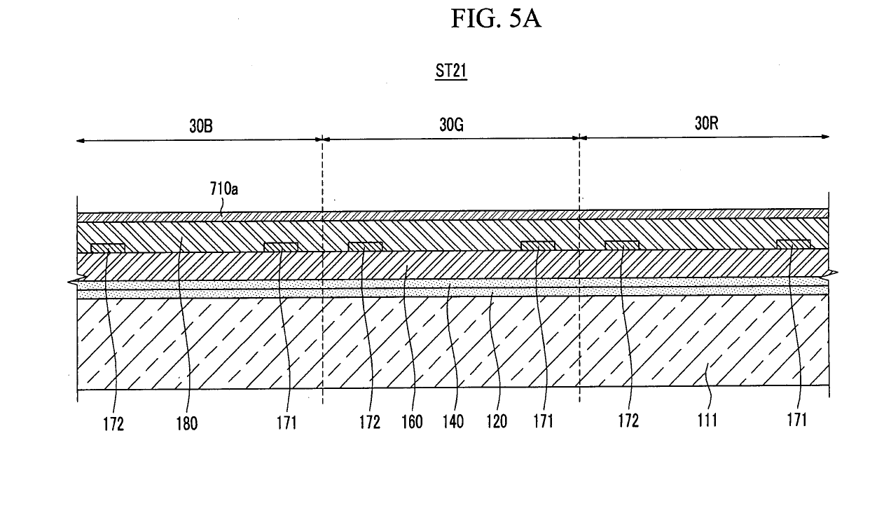

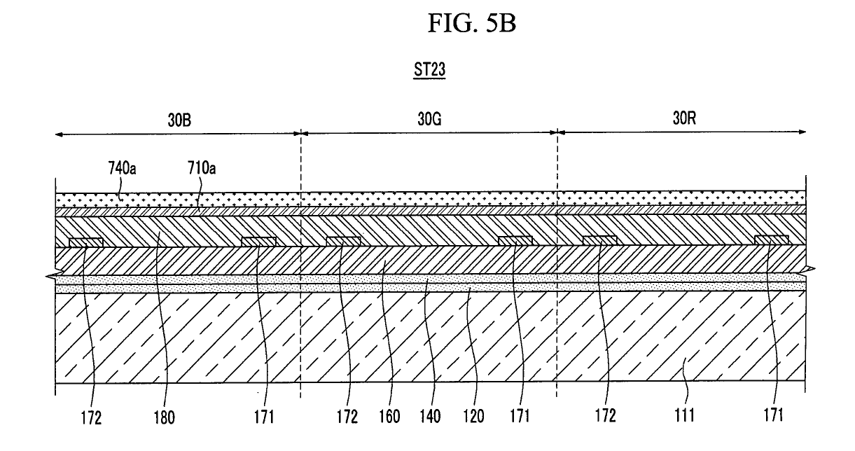

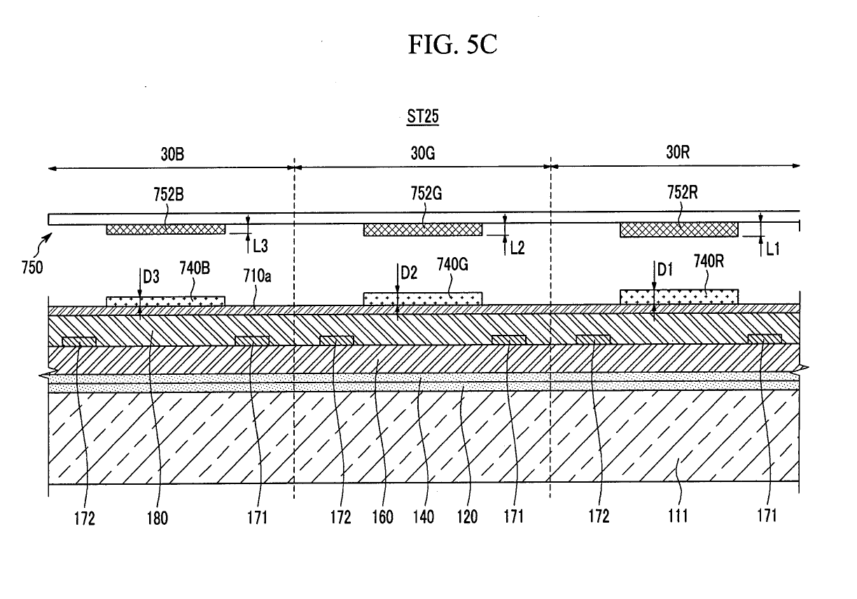

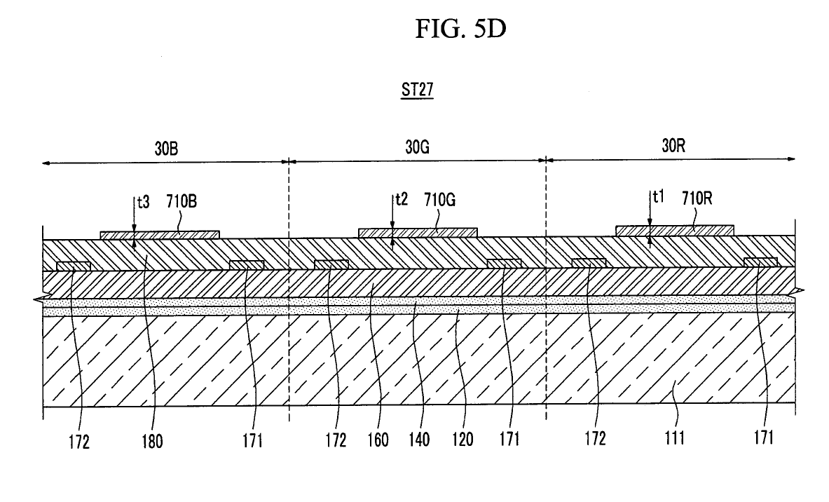

A method of manufacturing the organic light emitting diode (OLED) display 101 according to an embodiment will now be described with reference to FIG. 4 and FIG. 5A to FIG. 5D, wherein the red, green, and blue pixel electrodes 710R, 710G, and 710B are formed with different thicknesses.

FIG. 4 illustrates a flowchart of a method for manufacturing an organic light emitting diode (OLED) display according to a second example embodiment.

Referring to FIG. 4, the method may include operations of providing a substrate ST10, forming a pixel electrode (a first electrode) ST20, forming a pixel definition layer ST30, forming an emission layer ST40, and forming a common electrode (a second electrode) ST50.

In operation ST10, the substrate defined with a red pixel (the first pixel) (reference numeral 30R of FIG. 1 and FIG. 3), a green pixel (the second pixel) (reference numeral 30G of FIG. 1 and FIG. 3), and a blue pixel (the third pixel) (reference numeral 30B of FIG. 1 and FIG. 3) light emitting the different colors may be provided. Before the pixel electrode (reference numeral 710 of FIGS. 1 to 3) is formed, the substrate may be provided with a planarization layer (reference numeral 180 of FIG. 2).

In operation ST20, red, green, and blue pixel electrodes (reference numerals 710R, 710G, and 710B of FIG. 3) having respectively different thicknesses may be formed on the red pixel 30R, the green pixel 30G, and the blue pixel 30B, respectively.

In operation ST30, the pixel definition layer (reference numeral 190 of FIGS. 1 to 3) having an opening (reference numeral 199 of FIGS. 2 and 3) exposing the red, green, and blue pixel electrodes 710R, 710G, and 710B may be provided.

In operation ST40, the red, green, and blue emission layers 720R, 720G, and 720B (respectively corresponding to the red, green, and blue pixels 30R, 30G, and 30B) may be formed in respective openings 199 of the pixel definition layer 190.

In operation ST50, the common electrode 730 may be formed on the pixel definition layer 190 and on the red, green, and blue emission layers 720R, 720G, and 720B.

The providing of the substrate ST10, the forming of the pixel definition layer ST30, the forming of the emission layer ST40, and the forming of the common electrode ST50 may be realized through various generally known methods, details of which are known to those of skill in the art and need not be repeated.

Hereinafter, the method of forming the pixel electrode ST20 through the forming of the red, green, and blue pixel electrodes 710R, 710G, and 710B having different thicknesses will be described.

The forming of the pixel electrode ST20 may include forming a pixel electrode material layer (first electrode material layer) ST21, forming a photoresist material layer ST23, forming a photoresist pattern ST25, and etching the photoresist pattern and the pixel electrode material layer ST27. These operations will now be described with reference to FIG. 5A to FIG. 5D.

FIG. 5A to FIG. 5D illustrate cross-sectional views of stages in a process of forming red, green, and blue pixel electrodes in an organic light emitting diode (OLED) display according to a third example embodiment.

Referring to FIG. 5A, in the operation ST21 of forming the pixel electrode material layer, a pixel electrode material layer 710a for the pixel electrode 710 may be formed on the planarization layer 180.

Referring to FIG. 5B, in the operation ST23 of forming the photoresist material layer, a photoresist material layer 740a may be formed on the pixel electrode material layer 710a. In the present embodiment, a positive photoresist material layer 740a, of which a portion receiving light, i.e., an exposed portion, is removed in the developing process, is used as an example.

Next, referring to FIG. 5C, in the operation ST25 of forming the photoresist pattern, a photoresist material layer (reference numeral 740a of FIG. 5B) may be exposed by using a mask 750 to form photoresist patterns 740R, 740G, and 740B having different thicknesses, the photoresist patterns 740R, 740G, and 740B being respectively formed in the red, green, and blue pixels 30R, 30G, and 30B. Each of the photoresist patterns 740R, 740G, and 740B may have non-zero thicknesses.

In an implementation, when forming the photoresist pattern 740R, 740G, and 740B, the mask 750 allows different amounts of exposure in the red, green, and blue pixels 30R, 30G, and 30B. For example, the mask 750 may include light blocking patterns 752R, 752G, and 752B having different thicknesses corresponding to the red, green, and blue pixels 30R, 30G, and 30B. In the example illustrated in FIG. 5C, the thickness L2 of the light blocking pattern 752G of the green pixel 30G is greater than the thickness L1 of the light blocking pattern 752R of the red pixel 30R, and the thickness L3 of the light blocking pattern 752B of the blue pixel 30B is greater than the thickness L2 of the light blocking pattern 752G of the green pixel 30G. The light blocking patterns 752R, 752G, and 752B may include chromium that effectively blocks the light.

Using the mask described above, the exposure amount in the light blocking pattern 752R of the red pixel 30R is less than the exposure amount in the light blocking pattern 752G of the green pixel 30G, and the exposure amount in the light blocking pattern 752G of the green pixel 30G is less than the exposure amount in the light blocking pattern 752B of the blue pixel 30B. Thus, the photoresist material 740a made of the positive photoresist material may be removed (upon developing) in an amount that is increased as the exposure amount is increased. For example, a thinner light blocking pattern, e.g., 740B, may result in a greater exposure amount and more positive photoresist material being removed.

In the example shown in FIG. 5C, following development of the exposed photoresist the photoresist pattern 740R of the red pixel 30R has the first thickness D1, the photoresist pattern 740G of the green pixel 30G has the second thickness D2 that is less than the first thickness D1, and the photoresist pattern 740B of the blue pixel 30B has the third thickness D3 that is less than the second thickness D2. Also, the exposure amount may be sufficiently large at the portion corresponding to the portion where the light blocking patterns 752R, 752G, and 752B are not formed such that the entire thickness of the photoresist material layer 740a is removed there.

Next, as shown in FIG. 5D, the photoresist patterns 740R, 740G, and 740B and the pixel electrode material layer (reference numeral 740a of FIG. 5C) may be dry-etched, e.g., using plasma etching. The photoresist patterns 740R, 740G, and 740B having respective thicknesses may be used as etch controllers to simultaneously form pixel electrodes having respective thicknesses, where a thicker photoresist pattern results in a thicker, i.e., less-etched, pixel electrode. In an implementation, the thickest pixel electrode may have a thickness corresponding to that of the initial pixel electrode material layer, i.e., one of the pixel electrodes may be patterned without etching through the respective overlying photoresist pattern. In an implementation, the thickness t1 of the thickest pixel electrode, e.g., 710R in FIG. 5D, may be substantially the same as that of the pixel electrode material layer 710a.

In the example shown in FIG. 5D, the photoresist pattern 740R (corresponding to the red pixel 30R and having the greatest first thickness D1) controls the etching such that the red pixel electrode 710R has the greatest thickness t1 after the dry etching. Also, the photoresist pattern 740G (corresponding to the green pixel 30G and having the second thickness D2 that is less than first thickness D1) controls the etching such that the green pixel electrode 710G has a thickness less than the red pixel electrode 710R after the dry etching. Further, the photoresist pattern 740B (corresponding to the blue pixel 30B and having the thinnest third thickness D3) controls the etching such that the blue pixel electrode 710B has the smallest thickness t3 after the dry etching. In addition, the whole pixel electrode material layer 710a may be removed in the areas where the photoresist patterns 740R, 740G, and 740B are not formed.

The red, green, and blue pixel electrodes 710R, 710G, and 710B having different thicknesses may be formed at one time by using the photoresist patterns 740R, 740G, and 740B having the different thicknesses, such that the number of deposition processes, exposures, and etching processes may be reduced.

In contrast, using a conventional approach to form electrodes having different thicknesses would involve forming the red organic emission layer from three films, the green organic emission layer from two films, and the blue organic emission layer from one film. In such a case, when forming three films or two films of the red organic emission layer and the green organic emission layer, the portion deposited on the blue organic emission layer must be removed. However, defects, e.g., wherein a portion of the blue organic emission layer is damaged, may be generated in this process. Also, such a manufacturing process would be complicated by the additional deposition process and patterning process involved therein, such that productivity may be decreased. Moreover, where a light emitting assistance layer is used to compensate for the organic emission layer having low efficiency, the light emitting assistance layer must be deposited by using a very fine metal mask, such that the possibility of defect generation and increased material cost may further occur.

In the embodiments described above, electrodes having different thicknesses corresponding to different luminous efficiencies of the emitting materials may be formed at one time, such that the manufacturing process may be simplified and the material costs may be significantly reduced.

### DESCRIPTION OF SYMBOLS USED TO ILLUSTRATE EXAMPLE EMBODIMENTS IN THE DRAWINGS

30: pixel
30R: red pixel
30G: green pixel
30B: blue pixel
70: organic light emitting element
710: pixel electrode
720: organic emission layer
730: common electrode
710R: green pixel electrode
710G: red pixel electrode
710B: blue pixel electrode
720R: green organic emission layer
720G: red organic emission layer
720B: blue organic emission layer
740R, 740G, 740B: photoresist pattern
750: mask
752R, 752G, 752B: light blocking pattern.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method for manufacturing an organic light emitting diode (OLED) display, the method comprising:
forming a first electrode having different thicknesses corresponding to a first pixel, a second pixel, and a third pixel;
forming a first emission layer, a second emission layer, and a third emission layer respectively corresponding to the first pixel, the second pixel, and the third pixel; and
forming a second electrode on the first emission layer, the second emission layer, and the third emission layer,
wherein forming the first electrodes includes:
forming a first electrode material layer on the substrate,
forming a photoresist pattern having different thicknesses corresponding to the first pixel, the second pixel, and the third pixel, respectively, and
etching the first electrode material layer along with the photoresist pattern.

2. The method as claimed in claim 1, wherein:
the first electrode corresponding to the first pixel is thicker than the first electrode corresponding to the second pixel, and
the first electrode corresponding to the second pixel is thicker than the first electrode corresponding to the third pixel.

3. The method as claimed in claim 1, wherein:
the photoresist pattern corresponding to the first pixel has a first thickness,
the photoresist pattern corresponding to the second pixel has a second thickness that is less than the first thickness, and
the photoresist pattern corresponding to the third pixel has a third thickness that is less than the second thickness.

4. The method as claimed in claim 3, wherein the photoresist pattern is formed using a mask that provides respectively different amounts of exposure to each of the first pixel, the second pixel, and the third pixel.

5. The method as claimed in claim 4, wherein, in the mask, the exposure amount of the photoresist pattern corresponding to the first pixel is less than the exposure amount of the photoresist pattern corresponding to the second pixel, and the exposure amount of the photoresist pattern corresponding to the second pixel is less than the exposure amount of the photoresist pattern corresponding to the third pixel.

6. The method as claimed in claim 5, wherein:
the mask includes light blocking patterns corresponding to the first pixel, the second pixel, and the third pixel, respectively, and
the light blocking pattern corresponding to the first pixel is thicker than the light blocking pattern corresponding to the second pixel, and the light blocking pattern corresponding to the second pixel is thicker than the light blocking pattern corresponding to the third pixel.

7. The method as claimed in claim 6, wherein the light blocking pattern includes chromium.

8. The method as claimed in claim 1, wherein the first electrode material layer is dry-etched through the photoresist pattern.

9. The method as claimed in claim 1, wherein the first pixel is a red pixel, the second pixel is a green pixel, and the third pixel is a blue pixel.

10. A method for manufacturing an organic light emitting diode (OLED) display, the method comprising:
forming a pixel electrode corresponding to a first pixel and a pixel electrode corresponding to a second pixel, where the first pixel includes an emission material having a first luminous efficiency and the second pixel has a second luminous efficiency that is greater than the first luminous efficiency; and
forming a second electrode on the first emission layer and the second emission layer,
wherein forming the pixel electrodes includes:
forming an electrode material layer on the substrate, and
simultaneously forming the pixel electrode corresponding to the first pixel and the pixel electrode corresponding to the second pixel by etching the electrode material layer using a photoresist pattern to control an amount of the electrode material layer that is removed by the etching, the photoresist pattern having a first thickness in a region corresponding to the first pixel and a second thickness in a region corresponding to the second pixel, the first thickness being greater than the second thickness.
